(19) United States
(12) Patent Application Publication
(10) Pub. No.: US 2013/0059241 A1
(43) Pub. Date: Mar. 7, 2013

(54) DEVELOPMENT PROCESSING METHOD AND DEVELOPMENT PROCESSING APPARATUS

(71) Applicants: Hideaki SAKURAI, Kawasaki-shi (JP); Masatoshi Terayama, Kawasaki-shi (JP)

(72) Inventors: Hideaki SAKURAI, Kawasaki-shi (JP); Masatoshi Terayama, Kawasaki-shi (JP)

(21) Appl. No.: 13/584,954

(22) Filed: Aug. 14, 2012

(30) Foreign Application Priority Data
Sep. 7, 2011 (JP) 2011-195210

(51) Int. Cl. G03F 7/30; G03B 27/52

(52) U.S. Cl. 430/30; 430/434; 355/27

(57) ABSTRACT

According to one embodiment, a monitor pattern is previously exposed together with a device pattern on a resist film, the monitor pattern is developed in a first development condition and a fault occurrence risk is quantified based on a check image. At this time, the range of a second development condition in which the number of faults becomes less than or equal to a permissible value with respect to the quantified fault occurrence risk is determined based on the relationship between fault occurrence risk information and the number of faults. Then, a third development condition in which the pattern dimension becomes a desired value in the second development condition is determined and the device pattern is developed in the thus determined third development condition.

### CROSS-REFERENCE TO RELATED APPLICATIONS

This application is based upon and claims the benefit of priority from Japanese Patent Application No. 2011-195210, filed Sep. 7, 2011, the entire contents of which are incorporated herein by reference.

### FIELD

Embodiments described herein relate generally to a development processing method and development processing apparatus for subjecting a resist film on which a desired pattern is exposed to a development process.

### BACKGROUND

Recently, attention is paid to EUV lithography using exposure light of a wavelength region (extreme ultraviolet [EUV]) having the wavelength of 13.5 nm at the center thereof. A mask used in the EUV lithography has a structure obtained by forming an absorption pattern on a multi-layered reflecting film (mask blanks) that has two types of layers with different reflectances alternately laminated on a glass substrate.

In order to form an EUV exposure mask, a mask blanks substrate having a light-shielding film (to-be-processed film) as an absorber formed on a multi-layered reflecting film is used. A resist pattern is formed by exposing a resist film coated on the mask blanks substrate in a desired pattern by use of an electron beam and subjecting the same to a development process. Then, the light-shielding film is selectively etched with the resist pattern used as a mask. Therefore, if a fault is present in the resist pattern, a fault will occur in the pattern of the EUV exposure mask.

At the formation time of the EUV exposure mask, an extremely thin poor solubility thin film may occur on the surface of the resist film in some cases. Since the poor solubility thin film is extremely thin, the film may be twisted or broken because of a flow of a developing solution during the development process. The broken poor solubility thin film may move in the developing solution, may be caught on a resist film in a different location and adhered thereto. At this time, the film changes the pattern dimension and degrades line edge roughness (LER). In the worst case, a pattern fault may occur.

### BRIEF DESCRIPTION OF THE DRAWINGS

FIG. 1A is a plan view showing a state before development, for illustrating a development processing method according to a first embodiment.

FIG. 1B is a cross-sectional view showing a state before development, for illustrating a development processing method according to a first embodiment.

FIG. 2A is a plan view showing a state after developing a monitor pattern, for illustrating the development processing method according to the first embodiment.

FIG. 2B is a cross-sectional view showing a state after developing a monitor pattern, for illustrating the development processing method according to the first embodiment.

FIG. 3A is a plan view showing a state after developing a device pattern, for illustrating the development processing method according to the first embodiment.

FIG. 3B is a cross-sectional view showing a state after developing a device pattern, for illustrating the development processing method according to the first embodiment.

FIGS. 4A and 4B are views showing images obtained by photographing a monitor pattern by use of a CCD camera.

FIGS. 5A to 5C are characteristic diagrams each showing the relationship between fault occurrence risk information and the number of faults and the relationship between the number of faults and a development condition.

FIGS. 6A to 6D are characteristic diagrams each showing the relationship between fault occurrence risk information and the number of faults and the relationship between the number of faults and a rinsing condition, for illustrating a second embodiment.

FIG. 7 is a cross-sectional view showing the configuration of a nozzle head portion, for illustrating a development processing apparatus according to a third embodiment.

FIG. 8 is a plan view showing the positional relationship between the nozzle head portion and a substrate, for illustrating the development processing apparatus according to the third embodiment.

### DETAILED DESCRIPTION

In general, according to one embodiment, a monitor pattern is previously exposed together with a device pattern on a resist film, the monitor pattern is developed in a first development condition and a fault occurrence risk is quantified based on a check image obtained by checking the developed monitor pattern. At this time, the range of a second development condition in which the number of faults becomes less than or equal to a permissible value with respect to the quantified fault occurrence risk is determined based on the relationship between fault occurrence risk information and the number of faults for different development conditions previously acquired. Then, a third development condition in which the pattern dimension becomes a desired value in the second development condition is determined and the device pattern is developed in the thus determined third development condition.

It is understood based on the study by the inventor of this application and others that the probability of occurrence of the poor solubility thin film described above varies depending on post-coating delay (PCD, the deferment time after coating), exposure condition dependency including a fogging effect caused by a difference in the optical system of an electron beam (EB) exposure apparatus, a post-exposure baking (PEB) condition of PEB temperature, time and the like and a development condition of development time, temperature and the like.

Further, the following development technique is studied to optimize the development condition. A resist-sensitive monitor pattern is arranged on a region of a to-be-processed substrate surface other than a main pattern region, for example, on an edge portion thereof. Only the monitor pattern portion is previously developed and information related to the resist sensitivity is acquired from the monitor pattern portion. Then, a development condition suitable for the thus acquired resist sensitivity is feed-forwarded. In this method, the dimension can be controlled by quantifying the dimension variation risk such as the resist sensitivity before developing the main pattern. However, it is difficult to previously quantify the risk for a fault that is another large control item.

Based on the experiments by the inventor of this application and others, it is understood that something that becomes a source of the fault is already known in the course of development and it is understood that the fault risk can be measured. In the mask substrate, a region used for wafer exposure is limited and a region in which dimension control and fault control are required and a region in which such control is not required are provided. Therefore, a fault risk determination monitor pattern is arranged in the region in which the dimension control and fault control are required and a pattern obtained by developing the above pattern is checked. As a result, the fault risk can be quantified. The present embodiment is to optimize the development processing condition based on the above fact.

Next, the development processing method and development processing apparatus of this embodiment are explained with reference to the drawings.

### First Embodiment

In this embodiment, a case wherein an EUV mask is formed is explained as an example.

A multi-layered reflecting film and light-shielding film are formed on the surface of a substrate with the low coefficient of thermal expansion such as glass and a photosensitive thin film (resist film) is coated thereon. The resist film is exposed by means of an electron-beam drawing apparatus. After this, PEB is performed to form a latent image in the resist film. On the edge portion of the substrate, a fault risk determination monitor pattern and resist-sensitive monitor pattern are arranged. In this example, as the fault risk determination monitor pattern, an extraction pattern of 1 mm is used.

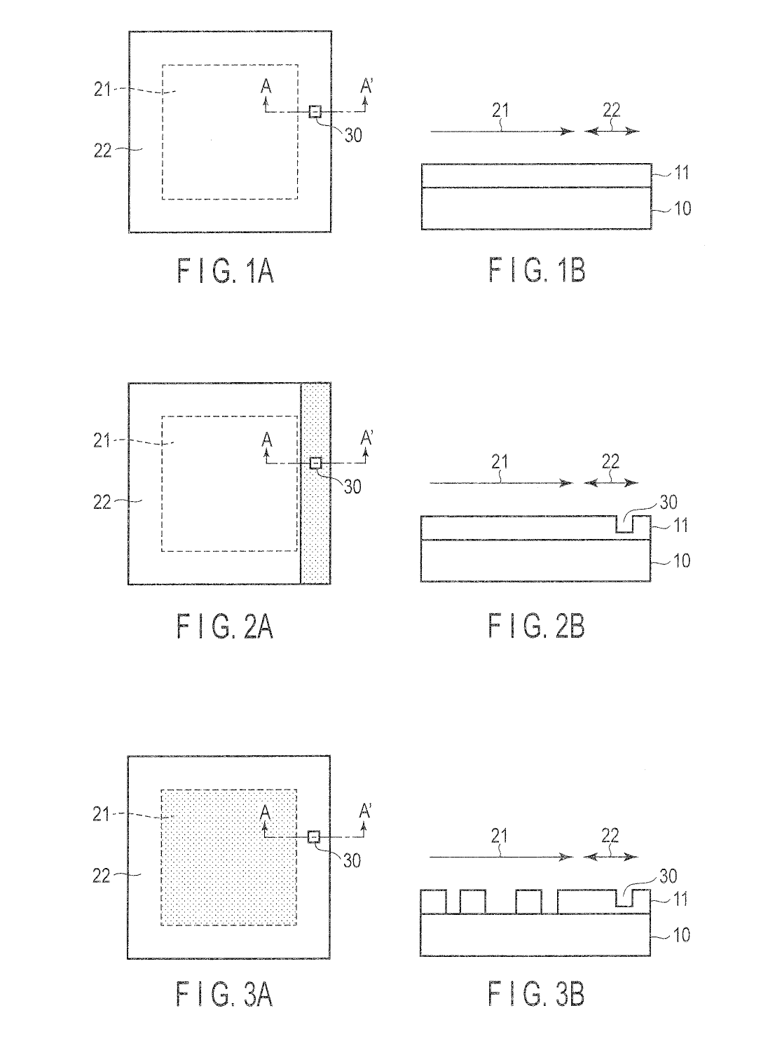

FIGS. 1A, 1B to FIGS. 3A, 3B show a process flow of this embodiment. In FIGS. 1A, 1B to FIGS. 3A, 3B, FIGS. 1A, 2A, 3A are plan views and FIGS. 1B, 2B, 3B are cross-sectional views taken along lines A-A′ of FIGS. 1A, 2A, 3A.

As shown in FIGS. 1A, 1B, a resist film 11 is coated on a mask blanks substrate 10 having a multi-layered reflecting film or light-shielding film. A desired device pattern is exposed on a device region 21 that requires dimension control and fault control of the resist pattern 11. Further, a fault risk determination monitor pattern 30 is exposed to a peripheral monitor region 22 surrounding the device region 21. A sensitive monitor pattern may be formed separately from the fault risk determination monitor pattern 30 or the fault risk determination monitor pattern 30 may be used instead thereof.

Next, as shown in FIGS. 2A, 2B, a portion of the monitor region 22 including the fault risk determination monitor pattern 30 is subjected to a development process in a first development condition in which the resist film 11 is approximately half-dissolved. At this time, the development process for the device region 21 that requires the dimension control and fault control is not performed.

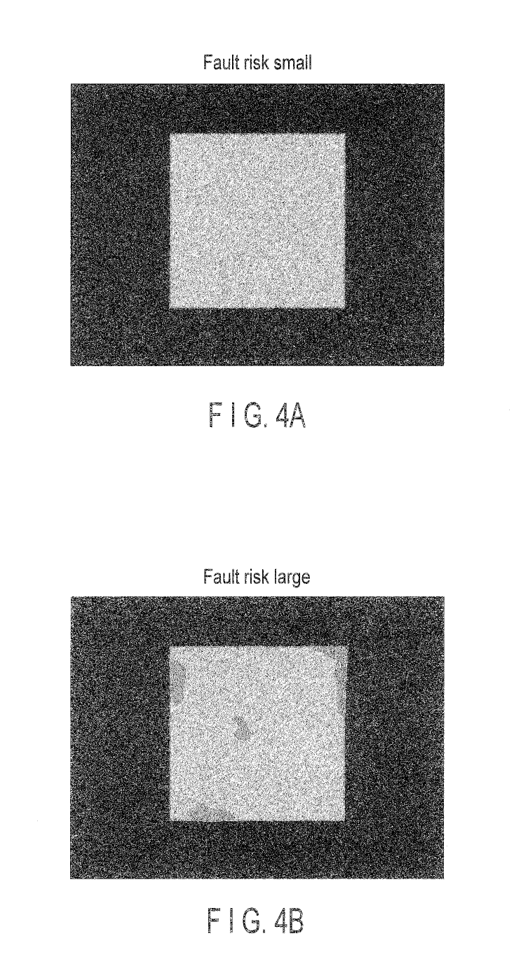

Next, an image of the monitor pattern is acquired by photographing the half-dissolved fault risk determination monitor pattern 30 by means of a CCD camera or the like. Examples of images obtained at this time are shown in FIGS. 4A, 4B. FIG. 4A shows a case wherein the fault risk is small and FIG. 4B shows a case wherein the fault risk is large. Since the resist dissolving speed is different depending on the location in the fault risk determination monitor pattern 30, contrast occurs because of a difference in the resist film thickness. A normal portion and abnormal portion are separated based on the acquired contrast and the total area of the abnormal portion is calculated. That is, the total area of regions in which the contrast for the normal portion in the exposed portion becomes greater than or equal to a desired value is calculated. Then, the fault occurrence risk can be quantified based on the total area.

It is considered that the fault occurrence risk varies in proportion to the area of the poor solubility thin film. Therefore, the fault occurrence risk can be quantified with high precision by calculating the area of the poor solubility thin film on the monitor pattern based on the image obtained by means of a CCD camera or the like.

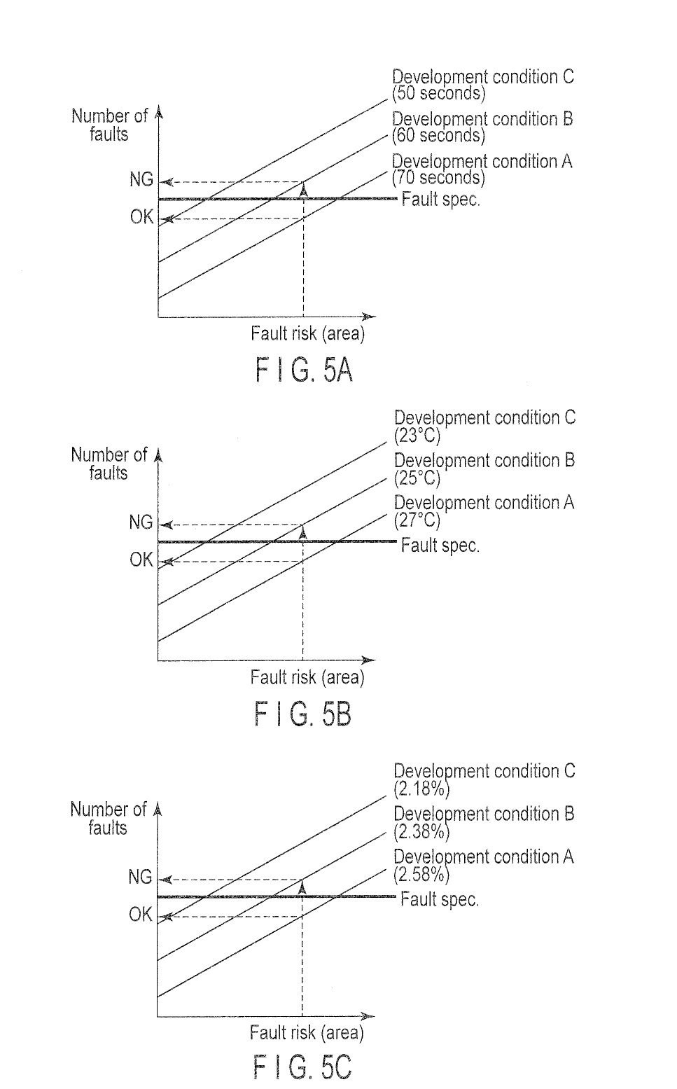

Determination of the normal portion and abnormal portion at this time is performed as follows. That is, a substrate for testing that is the same as a substrate used for actually forming a mask is previously prepared, a fault risk determination monitor pattern 30 is half-dissolved on the above substrate and the luminance of each pixel is calculated. Then, after development of the resist and etching of the substrate, the fault checking process is finally performed on the entire surface of a mask. Thus, correlation data of the area of the abnormal portion or the size of a fault and the number of faults is acquired. The data items are acquired in plural development conditions (development conditions A, B, C). As shown in FIGS. 5A to 5C, the acquired correlation data is formed in a table form or graph form. FIG. 5A shows data obtained when the development time is changed, FIG. 5B shows data obtained when the developing solution temperature is changed and FIG. 5C shows data obtained when the concentration of the developing solution is changed.

The permissible range of the development condition of the device region 21 that requires the dimension control and fault control is determined based on the relationship between the total area of the abnormal portions obtained when the fault risk determination monitor pattern 30 is half-dissolved, information such as permissible fault specifications and the graphs shown in FIGS. 5A to 5C. For example, since the number of faults for the fault risk in development condition B that is a normal development condition is NG, development condition A in which the number of faults for the same fault risk is OK is selected. As a result, the range of the second development condition in which the number of faults can be suppressed within a permissible value can be determined for the substrate 10.

Next, a third development condition in which desired pattern dimension is obtained is further selected in the range of the second development condition. Specifically, a development processing condition in which the pattern is finished with desired dimension can be attained by determining the state of resist-sensitive monitor pattern and acquiring sensitivity information of the resist film 11 before the development process. The third development condition that satisfies both of the above condition and the second development condition is set. Then, as shown in FIGS. 3A and 3B, the device region 21 that requires the dimension control and fault control is subjected to the development process. After this, a rinsing process and drying process are performed to form a resist pattern.

The thus obtained pattern is checked and then it can be confirmed that the number of faults is reduced while the absolute value of the dimension of the resist pattern is suppressed within desired specifications.

In the feed-forward development method using the fault risk determination monitor pattern of this embodiment, several desired forms are present. In this embodiment, the extraction pattern is used as the fault risk determination monitor pattern, but other types of patterns of lines-and-spaces, isolated lines, isolated spaces and the like may be used instead of this pattern. Further, this can be attained by adequately selecting the magnification of a CCD camera used for observing the pattern size, monitor pattern and the like.

In the first development condition, the degree of dissolution may be sufficient if all of the resist film is not dissolved. Preferably, the dissolution amount that permits the fault risk to be highly sensitively monitored may be selected by changing the degree of dissolution.

Further, as the method for processing a portion of the substrate on which the resist film is coated, any type of method can be used.

The second development condition may be sufficient if the development condition can be changed by selecting a parameter that can change the dissolving characteristic of the resist film such as the development time, developing solution temperature, substrate temperature and the like.

Further, a mask that has less faults and in which desired lithography likelihood is attained can be formed by selecting a range in which the likelihood at the time of transfer of the mask pattern to the wafer can be attained as the permissible range of the development condition. In order to realize this, it is possible to previously acquire the relationship between the development condition and the pattern dimension and the relationship between the pattern dimension and the lithography likelihood and store the same as an internal table. In this case, the likelihood is the so-called lithography likelihood (the likelihood that causes the pattern dimension to be set in desired pattern dimension on the wafer when the exposure amount, focus or the like is changed).

Thus, according to this embodiment, the fault risk determination monitor pattern 30 is provided in the monitor region 22 formed around the device region 21. Then, the fault risk determination monitor pattern 30 is developed before the original development process and a development condition is set based on the contrast obtained at this time. As a result, the development process in which not only the pattern is controlled to desired dimension but also the fault occurrence can be suppressed can be performed. That is, an attempt can be made to control the resist pattern to the desired dimension and reduce the number of faults. Further, since the fault risk determination monitor pattern 30 is formed in the monitor region 22 that does not require the dimension control and fault control, no bad influence is given to the device region 21 in the process for determining the development condition of the device region 21.

### Second Embodiment

Next, a different example of forming an EUV mask is explained.

Like the first embodiment, a substrate having a multi-layered reflecting film and light-shielding film formed on the surface thereof and a resist film coated thereon is exposed by means of an electron-beam drawing apparatus. Then, PEB is performed to form a latent image in the resist film. Since the process flow diagram is the same as that shown in FIGS. 1A, 1B to FIGS. 3A, 3B, the drawing is omitted here.

First, a partial region on the substrate having a monitor region 22 formed thereon is subjected to a development process in a first development condition in which a resist film 11 is approximately half-dissolved. At this time, the development process for a device region 21 that requires the dimension control and fault control is not performed. Next, an image of the monitor pattern is acquired by photographing a half-dissolved fault risk determination monitor pattern 30 by means of a CCD camera. At this time, since the dissolving speed is different depending on the location in the fault risk determination monitor pattern 30, contrast occurs because of a difference in the resist film thickness. A normal portion and abnormal portion are separated based on the acquired contrast and the total area of the abnormal portion is calculated.

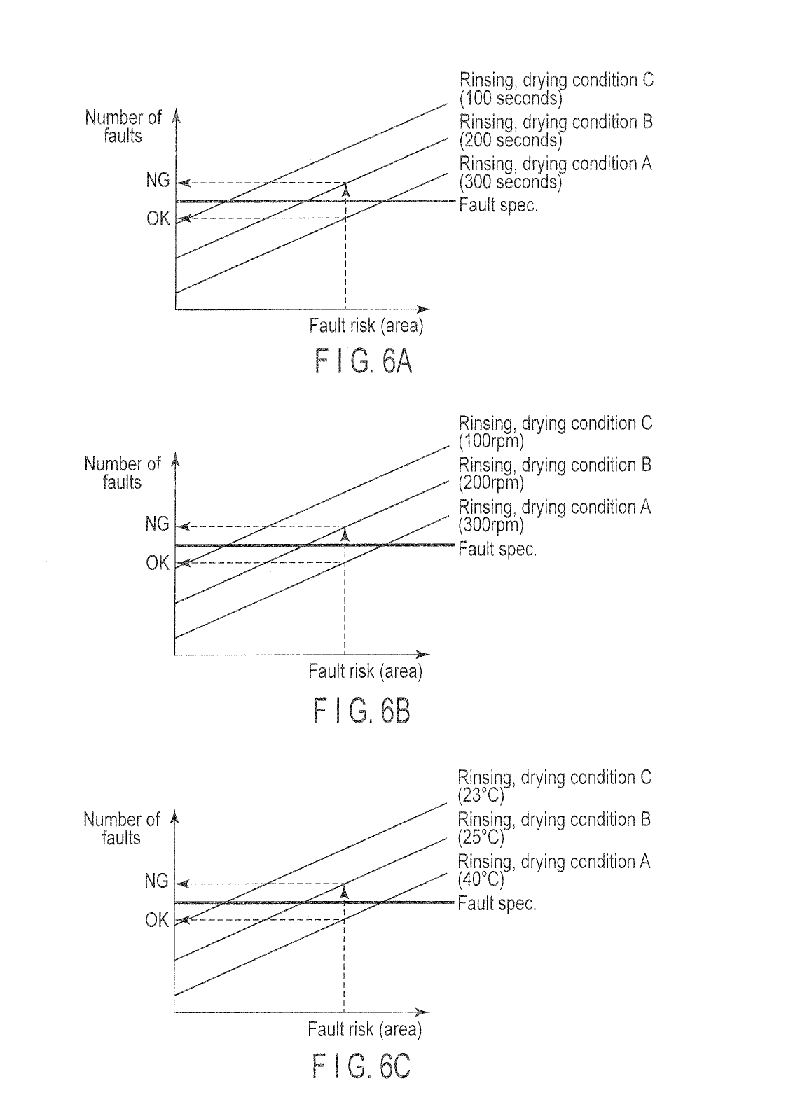

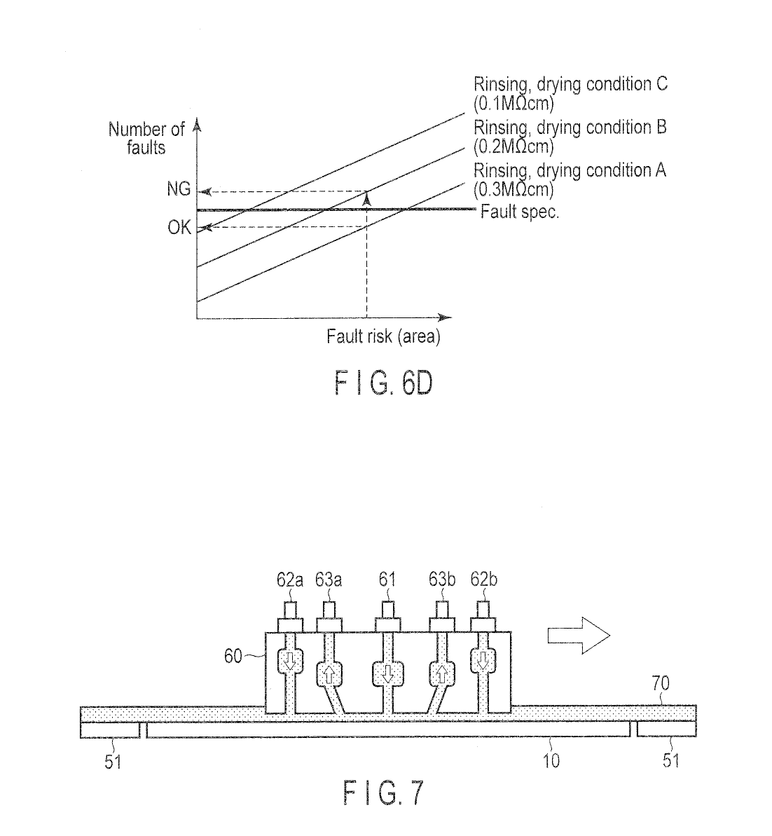

Further, the correlation data of the number of faults and the area (fault risk) of the previously acquired abnormal portion is acquired. The correlated data is acquired in each of plural rinsing conditions (more specifically, rinsing conditions and drying conditions) and the correlated data is formed in a table form or graph form as shown in FIGS. 6A to 6D. FIG. 6A shows data obtained when the rinse time is changed, FIG. 6B shows data obtained when the rinse rotation speed is changed, FIG. 6C shows data obtained when the rinsing solution temperature is changed and FIG. 6D shows data obtained when the amount of additives to the rinsing solution (the specific resistance of the rinsing solution) is changed. The development condition when the correlation data of the fault risk and the number of faults is acquired is a development condition in which desired pattern dimension is obtained. Further, the development condition is the same in each rinsing condition. Even in the same development condition, the relationship between the fault risk and the number of faults is changed if the rinsing condition is changed.

Next, after a development condition in which the desired pattern dimension is obtained is selected and the development process for the device region 21 that requires the dimension control and fault control is performed, the rinsing process is performed. In this rinsing process, rinsing condition A in which the number of faults is set to a permissible value is selected based on the calculated area of the abnormal portion and the tables shown in FIGS. 6A to 6D. Then, the rinsing process is performed in the selected rinsing condition and the drying process is performed to form a resist pattern.

The thus obtained pattern is checked and then it can be confirmed that the number of faults is reduced while the absolute value of the dimension of the resist pattern is suppressed within desired specifications.

Thus, according to this embodiment, the fault risk determination monitor pattern 30 is provided in the monitor region 22 formed around the device region 21. Then, the fault risk determination monitor pattern is developed before the original development process and the rinsing condition is set based on the contrast obtained at this time. As a result, the rinsing process in which not only the pattern is controlled to desired dimension but also the fault occurrence is reduced can be performed. Therefore, the same effect as that of the first embodiment can be attained.

### Third Embodiment

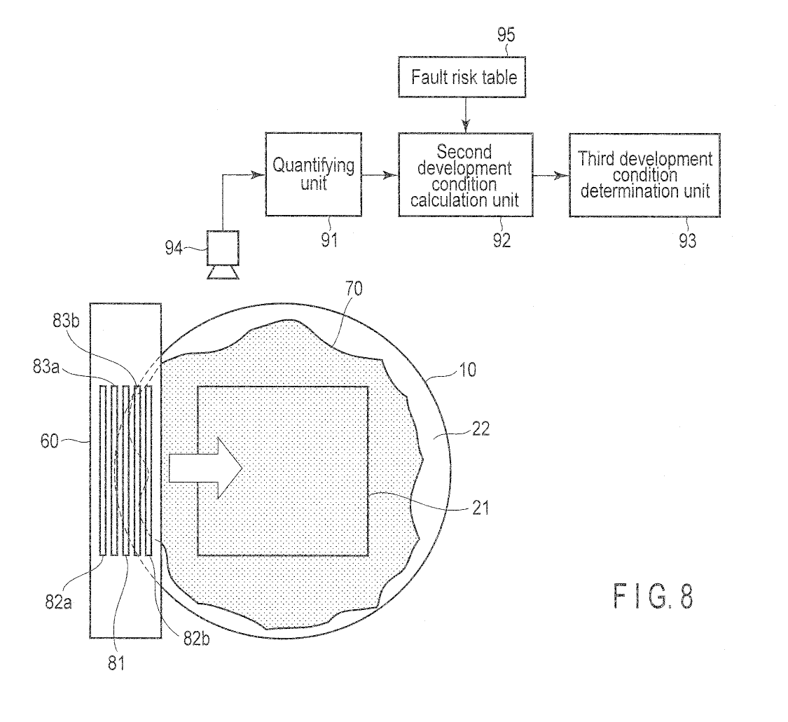

FIG. 7 and FIG. 8 illustrate a development processing apparatus according to a third embodiment, FIG. 7 is a cross-sectional view showing a nozzle head and FIG. 8 is a plan view showing the positional relationship between the nozzle head and a substrate.

A substrate 10 that is coated with a resist film and on which a desired pattern is exposed is placed on a stage that is not shown in the drawing. An auxiliary plate 51 used for reducing the step difference of a substrate edge portion is placed on the peripheral portion of the substrate 10. In this state, a nozzle head 60 is scanned on the surface of the substrate 10.

The nozzle head 60 includes a developing solution supply unit 61 used for supplying a developing solution, cleaning solution supply units 62a, 62b used for supplying cleaning solutions and discharge units 63a, 63b used for discharging the developing solution and cleaning solution. The respective units have slit-like openings formed along the lengthwise direction of the nozzle head 60 in the undersurface of the nozzle head 60. That is, the developing solution supply unit 61 is connected to a slit-like developing solution supply port 81 formed in the central portion of the undersurface of the nozzle head 60 and the discharge units 63a, 63b are respectively connected to discharge ports 83a, 83b provided on both sides of the developing solution supply port. Further, the cleaning solution supply units 62a, 62b are respectively connected to slit-like cleaning solution supply ports 82a, 82b provided outside the discharge ports 83a, 83b.

As shown in FIG. 8, a liquid film 70 is formed on the surface of the substrate 10 by scanning the nozzle head 60 in a direction perpendicular to the slit direction and thus a device region 21 and monitor region 22 can be developed. Further, the device region 21 and monitor region 22 can be independently subjected to a development process by controlling the scan position of the nozzle head 60. Further, although not shown in the drawing, an image-sensing device such as a CCD used for checking a pattern after development is provided.

In this embodiment, the following three mechanisms 91 to 93 are provided in addition to the above structure. In the first mechanism (quantifying unit) 91, a pattern obtained by selectively developing the monitor region 22 is checked by use of a CCD camera 94 or the like and a fault occurrence risk is quantified based on the check result. The development condition (first development condition) at this time is a condition in which the resist film is half-dissolved. In the second mechanism (second development condition calculation unit) 92, a development condition (second development condition) in which the number of faults becomes less than or equal to a permissible value at the time of the quantified fault occurrence risk is calculated based on the relationship (fault risk table) 95 between the fault occurrence risk information and the number of faults and between the number of faults and the development condition. In the third mechanism (third development condition determination unit) 93, a development condition (third development condition) in which the pattern dimension becomes a desire value in the calculated development condition is determined.

By using this apparatus, the device region 21 and monitor region 22 can be independently subjected to the development process. The fault occurrence risk can be quantified by checking a pattern obtained by selectively developing the monitor region 22 by use of a CCD camera or the like. Then, a development condition in which the number of faults becomes less than or equal to a permissible value with respect to the quantified fault occurrence risk can be calculated based on the relationship between the number of faults and fault occurrence risk information with respect to different development conditions previously formed in the table form. Further, the development process as in the first embodiment described before can be performed by determining a development condition in which the pattern dimension becomes the desired value in the calculated development condition.

Therefore, in this embodiment, the same effect as that of the first embodiment can be attained. Further, in this embodiment, since the nozzle head 60 as shown in FIG. 7 is used, an advantage that it becomes easy to independently subject the device region 21 and pattern region 22 to the development process can be attained.

### Modification

This invention is not limited to the above embodiments. In the above embodiments, the EUV exposure mask is explained as an example, but the mask is not limited to the EUV exposure mask and various masks can be used. Further, the process is not necessarily limited to the mask development process and can be applied to a process if resist formed on the substrate is developed.

Further, the apparatus configuration for performing the development process is not necessarily limited to the configuration shown in FIG. 7 and FIG. 8 and any configuration in which the device region and monitor region can be independently subjected to the development process can be applied. Further, a detector for checking the monitor pattern is not limited to the CCD camera. It is sufficient if an image of the developed monitor pattern can be acquired. In the embodiments, one monitor pattern is used, but a plurality of monitor patterns are used and fault occurrence risks obtained based on the monitor patterns may be averaged.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A development processing method comprising:
developing a monitor pattern in a first development condition with respect to a to-be-processed substrate on which a resist film is coated and the monitor pattern is exposed on the resist film together with a device pattern,
quantifying a fault occurrence risk based on a check image obtained by checking the developed monitor pattern,
determining a range of a second development condition in which the number of faults does not become greater than a permissible value at the time of the quantified fault occurrence risk based on a relationship between the number of faults and fault occurrence risk information with respect to different development conditions previously acquired, and
determining a third development condition in which pattern dimension becomes a desired value in the range of the second development condition and developing the device pattern in the determined third development condition.

2. The method according to claim 1, wherein the first development condition is a condition in which the resist film is half-dissolved.

3. The method according to claim 1, wherein the developed monitor pattern is photographed by means of a CCD camera to obtain the check image.

4. The method according to claim 3, wherein the quantifying the fault occurrence risk is quantifying the fault occurrence risk by calculating an area of a poor solubility thin film in the monitor pattern based on the check image obtained by means of the CCD camera.

5. The method according to claim 4, wherein the quantified fault occurrence risk is obtained in one of a table form and graph form and one of the table form and graph form is referred to when the range of the second development condition is set.

6. The method according to claim 1, wherein the quantifying the fault occurrence risk is calculating a total area of regions in which contrast of the check image with respect to a normal portion in an exposed portion does not become less than a desired value and quantifying the fault occurrence risk based on the total area.

7. The method according to claim 1, wherein a surface of the to-be-processed substrate is divided into a device region on which the device pattern is formed and a monitor region that surrounds the device region and on which the monitor pattern is formed.

8. A development processing method comprising:
developing a monitor pattern in a first development condition with respect to a to-be-processed substrate on which a resist film is coated and the monitor pattern is exposed on the resist film together with a device pattern,
quantifying a fault occurrence risk based on a check image obtained by checking the developed monitor pattern,
determining a range of a rinsing condition in which the number of faults does not become greater than a permissible value at the time of the quantified fault occurrence risk based on a relationship between the number of faults and fault occurrence risk information with respect to different rinsing conditions previously acquired,
developing the device pattern in a second development condition in which pattern dimension becomes a desired value after developing a region of the monitor pattern, and
performing a rinsing process for the to-be-processed substrate in the determined rinsing condition after developing the device pattern.

9. The method according to claim 8, wherein the first development condition is a condition in which the resist film is half-dissolved.

10. The method according to claim 8, wherein the developed monitor pattern is photographed by means of a CCD camera to obtain the check image.

11. The method according to claim 10, wherein the quantifying the fault occurrence risk is quantifying the fault occurrence risk by calculating an area of a poor solubility thin film in the monitor pattern based on the check image obtained by means of the CCD camera.

12. The method according to claim 8, wherein the quantifying the fault occurrence risk is calculating a total area of regions in which contrast of the check image with respect to a normal portion in an exposed portion does not become less than a desired value and quantifying the fault occurrence risk based on the total area.

13. The method according to claim 12, wherein the quantified fault occurrence risk is formed in one of a table form and graph form and one of the table form and graph form is referred to when a range of the second development condition is set.

14. The method according to claim 8, wherein a surface of the to-be-processed substrate is divided into a device region on which the device pattern is formed and a monitor region that surrounds the device region and on which the monitor pattern is formed.

15. A development processing apparatus comprising:
a development mechanism configured to independently develop a device region and monitor region with respect to a to-be-processed substrate having a device pattern exposed on a resist film on the device region and a monitor pattern exposed on a resist film on the monitor region,
a quantifying unit configured to quantify a fault occurrence risk obtained by developing the monitor region in a first development condition,
a calculation unit configured to calculate a range of a second development condition in which the number of faults does not become greater than a permissible value with respect to the quantified fault occurrence risk based on a relationship between the number of faults and fault occurrence risk information with respect to different development conditions, and
a determination unit configured to determine a third development condition in which pattern dimension becomes a desired value in the second development condition.

16. The apparatus according to claim 15, wherein the development mechanism includes a nozzle head scanned on the to-be-processed substrate, and the nozzle head includes a slit-like developing solution supply port formed to supply a developing solution to a surface of the substrate, a slit-like cleaning solution supply port formed to supply a cleaning solution to the surface of the substrate and a slit-like discharge port formed to discharge the developing solution and cleaning solution from the surface of the substrate.

17. The apparatus according to claim 15, wherein the developing solution supply port, cleaning solution supply port and discharge port are arranged in parallel and the nozzle head is scanned in a direction perpendicular to the slit direction.
